(19) United States
(12) Patent Application Publication
(10) Pub. No.: US 2019/0008048 A1
(43) Pub. Date: Jan. 3, 2019

(54) BREAD BOARD, BREAD BOARD SYSTEM AND NON-TRANSITORY COMPUTER READABLE MEDIUM

(71) Applicants: Kabushiki Kaisha Toshiba, Tokyo (JP); Toshiba Electronic Devices & Storage Corporation, Tokyo (JP)

(72) Inventor: Hajime Sano, Katsushika Tokyo (JP)

(21) Appl. No.: 15/919,634

(22) Filed: Mar. 13, 2018

(30) Foreign Application Priority Data
Jun. 29, 2017 (JP) 2017-127844

(51) Int. Cl. H05K 1/18; H01R 12/51

(52) U.S. Cl. CPC H05K 1/184; H01R 12/515; H05K 2201/10106; H05K 2201/09427; H05K 2201/10151; H05K 2201/10053

(57) ABSTRACT

A bread board includes a first layer, a second layer, and connectors. The first layer includes a plurality of first regions each including at least one terminal detacher which is electrically connected to a terminal, and the terminal detachers contained in an identical one first region from among the plurality of first regions are mutually electrically connected, but are electrically insulated from the terminal detachers contained in other first regions. The second layer includes a plurality of second regions and forms a multilayer structure with the first layer. Each of the connectors electrically connects the second region of the second layer and a predetermined first region of the first layer, and the plurality of first regions which are mutually insulated are electrically connected through the connector and the second region.

### CROSS-REFERENCE TO RELATED APPLICATIONS

This application is based upon and claims the benefit of priority from the prior Japanese Patent Application No. 2017-127844, filed on Jun. 29, 2017, the entire contents of which are incorporated herein by reference.

### FIELD

The embodiments of the present invention relate to a bread board, bread board system and non-transitory computer-readable medium.

### BACKGROUND

A bread board, in particular, a solderless bread board is widely used in creation of a prototype of an electronic circuit. Since this bread board includes insertion ports capable of attaching/detaching terminals which enable to freely detach circuit elements such as a resistor, a capacitor, an inductor, and so on, it is a very effective device for prototyping of various circuits.

However, in most cases, it is necessary to locate jumper wires on the bread board to connect terminals of the elements with each other when the prototyping of a circuit is carried out. The more complicated the circuit becomes, the more jumper wires are required, and it becomes also complicated just to locate the jumper wires. Accordingly, taking a view of an entire circuit becomes difficult to lead to a locating error of the jumper wires. Further, distances between regions to be connected on the bread board are all different, and various lengths of jumper wires are required in accordance with these distances. It is therefore necessary to prepare the jumper wires having required lengths, or to prepare the jumper wire having the required length each time.

### BRIEF DESCRIPTION OF THE DRAWINGS

FIG. 1 is a plan view of a bread board according to an embodiment;

FIG. 2A and FIG. 2B are respectively an A-A sectional view and a B-B sectional view in FIG. 1;

FIG. 3 is a view illustrating an example of insertion ports of the bread board according to the embodiment;

FIG. 4 is a circuit diagram of the bread board according to the embodiment;

FIG. 5A to FIG. 5C are views each illustrating an example of a connector according to the embodiment;

FIG. 6 is a view illustrating an example of an element disposition at the bread board according to the embodiment;

FIG. 7 is a circuit diagram illustrating a circuit of FIG. 6;

FIG. 8 is a view illustrating another example of the bread board according to the embodiment;

FIG. 9A to FIG. 9D are views each illustrating an example of a connector according to the embodiment;

FIG. 10 is a block diagram illustrating functions of a bread board system according to the embodiment;

FIG. 11 is a circuit diagram of the bread board system according to the embodiment;

FIG. 12 is a view illustrating a flow of processes of the bread board system according to the embodiment;

FIG. 13 is a view illustrating a usage example of the bread board according to the embodiment;

FIG. 14 is a view illustrating another usage example of the bread board according to the embodiment; and

FIG. 15A to FIG. 16C are views illustrating examples of switches in the bread board according to the embodiment.

### DETAILED DESCRIPTION

According to one embodiment, a bread board includes a first layer, a second layer, and connectors. The first layer includes a plurality of first regions each including at least one terminal detacher which is electrically connected to a terminal, and the terminal detachers contained in an identical one first region from among the plurality of first regions are mutually electrically connected, but are electrically insulated from the terminal detachers contained in other first regions. The second layer includes a plurality of second regions and forms a multilayer structure with the first layer. Each of the connectors electrically connects the second region of the second layer and a predetermined first region of the first layer, and the plurality of first regions which are mutually insulated are electrically connected through the connector and the second region.

Embodiments will now be explained with reference to the accompanying drawings. The present invention is not limited to the embodiments.

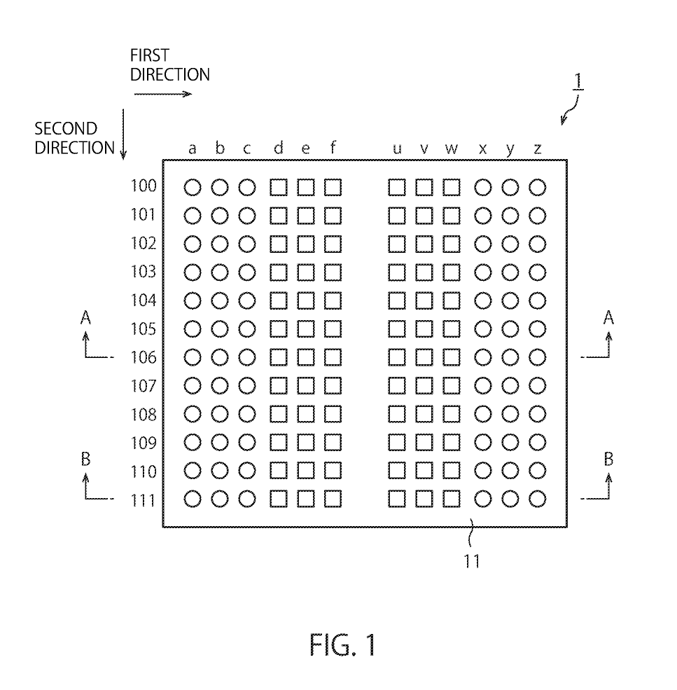

In the following explanation, it is explained a bread board having 12×12 insertion ports where two island regions each having 12×6 insertion ports are paired for the purpose of explanation, but a size of the bread board is not limited thereto, and the bread board may have an arbitrary size, the arbitrary number of insertion ports, and an arbitrary installation form within a general range. The island regions described here indicate, for example, a region containing columns of a to f and a region containing columns of u to z in FIG. 1 as a matter of convenience.

### First Embodiment

In the present embodiment, there is described a bread board which is a solderless bread board (hereinafter, it is just called a bread board) having a multilayer structure, in which a plurality of first regions are mutually insulated, insertion ports to attach/detach terminals of circuit elements provided at each of the first regions are electrically connected, and the first regions are insulated at a first layer, these insulated first regions are connected at a second layer to thereby enable the bread board without any jumper wire.

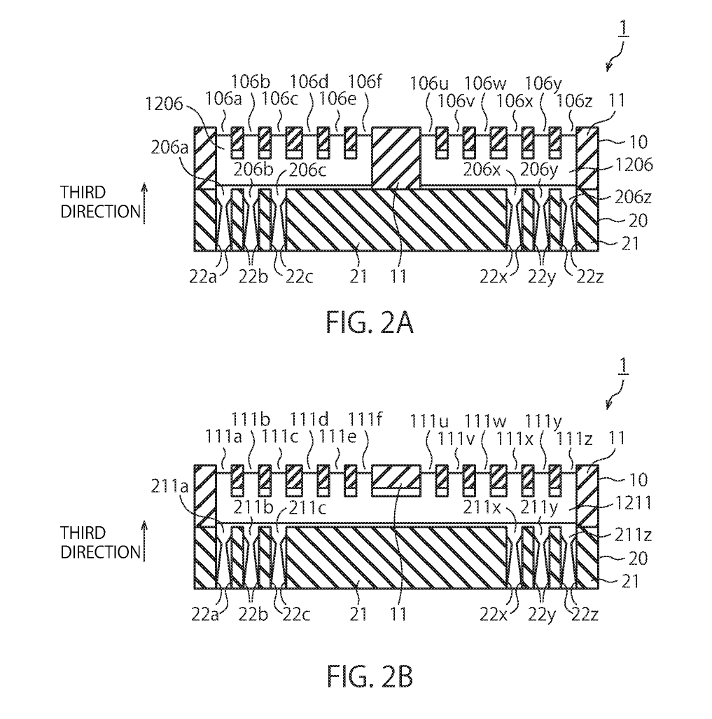

The multilayer structure of the bread board according to the present embodiment is described by using FIG. 1 and FIG. 2A, FIG. 2B. FIG. 1 is a plan view of a bread board 1 according to the present embodiment. FIG. 2A is an A-A sectional view, and FIG. 2B is a B-B sectional view in FIG. 1 of the bread board 1 according to the present embodiment.

In FIG. 1, insertion ports being terminal detachers which attach/detach terminals are circles in outside three columns on both sides, and the other are rectangles, but these are illustrated to distinguish for the purpose of explanation. The insertion ports may actually have the same shape or different shapes as illustrated in the drawing. As illustrated in FIG. 1, the bread board 1 is as same as a general bread board in a planar view. In the following description, directions are represented by a combination of a first direction (a horizontal direction in the drawing) and a second direction (a vertical direction in the drawing).

Meanwhile, the bread board 1 forms a multilayer structure, for example, a two-layer structure where a first layer 10 and a second layer 20 are laminated as illustrated by a sectional view in FIG. 2A. Hereinafter, first insertion ports being the insertion ports of the first layer 10 are represented by row numbers (100 to 111) and column numbers (a to f, u to z), and similarly, second insertion ports being the insertion ports of the second layer 20 are represented by row numbers (200 to 211) and column numbers (a to c, x to z) to be described. For example, the first insertion port at an uppermost left is represented as a first insertion port 100a, and a right-hand neighbor first insertion port is represented as a first insertion port 100b, in FIG. 1.

A laminated direction of the first layer 10 and the second layer 20 is set to be a third direction for convenience. For example, the first direction, the second direction, and the third direction are respectively orthogonal directions. Here, the orthogonal direction is not necessarily a strictly orthogonal direction but a state forming an angle which is generally regarded to be orthogonal.

First, the first layer 10 is described. As illustrated in FIG. 2A, the first layer 10 is formed by including first insertion ports 106 and a conductor 1206 located under each first insertion port 106 in an insulating substrate 11. Similar to a general bread board, respective first insertion ports are electrically connected in respective regions separated into left and right along the first direction, for example.

That is, terminals inserted into first insertion ports 106a, 106b, . . . , 106f are mutually electrically connected, and terminals inserted into first insertion ports 106u, 106v, . . . , 106z are mutually electrically connected. The terminals inserted into the first insertion port 106a and the first insertion port 106u existing at different first regions are insulated from one another. The left and right first regions are insulated by an insulating part of the substrate 11 provided between the conductors 1206.

The conductor 1206 is a conductor which has a contact making use of a leaf spring located along each first insertion port 106 along the first direction, for example. When the leaf spring is made use of, the terminal inserted into each first insertion port 106 is caught along the second direction, to have a structure where the terminal and the conductor 1206 have a contact. It is thereby possible to electrically connect the terminals inserted into the first insertion ports 106 at each of the first regions.

The conductor 1206 is located at each of the left and right first regions as illustrated in FIG. 2A, and thereby, the structure is enabled where the terminals inserted into the first insertion ports 106 are electrically connected in each of the left and right first regions, and the first insertion ports 106 striding over the left and right first regions are insulated. The first insertion ports existing at different rows from one another, for example, the first insertion port 106a and a first insertion port 107a are insulated by the structure similar to the later-described second layer 20.

The bread board 1 is different from a general bread board in a point that it is connected to second insertion ports provided at the second layer 20 located below the first layer 10. For example, in the first layer 10, a rear surface of the first insertion port which is connected to the second insertion port is formed such that the insulating substrate 11 is provided discontinuously.

The bread board 1 has a structure where the substrate 11 is discontinuously provided throughout the first region where the first insertion ports exist, but the structure is not limited thereto, and the bread board may have a structure where a connection port to be connected to the second insertion port is provided at a part of the rear surface of the substrate 11 of the first insertion port which is necessary to be connected to the second insertion port. As another example, the connection port may be provided at the rear surface of each first insertion port to have the same displacement as the first insertion port.

For example, a conductive or insulating shielding which does not disturb an operation of the leaf spring structure of the conductor 1206 may be provided between the first insertion port 106b and a second insertion port 206a so that a connector inserted into the first insertion port 106b is not connected to an insertion port such as the second insertion port 206a which is not the insertion port supposed to be connected.

Next, the second layer 20 is described. The second layer 20 is constituted by including second insertion ports 206 at an insulating substrate 21. There are the first regions which are electrically connected along the first direction at the first layer 10, meanwhile, there are second regions which are electrically connected along the second direction at the second layer 20. That is, the relationship between second insertion ports 200a to 211a and a conductor 22a of the second layer 20 corresponds to, for example, the relationship between the first insertion ports 106a to 106f and the conductor 1206 of the first layer 10.

The second layer 20 is formed by including the second insertion ports 206 and conductors 22 located below the respective second insertion ports 206 in the insulating substrate 21. The second layer 20 is formed to include the second regions along the second direction, where terminals inserted into the second insertion ports 200a, 201a, . . . , 211a provided at the second region are mutually electrically connected, meanwhile terminals inserted into second insertion ports along the first direction, for example, second insertion ports 206a, 206b, . . . , 206z are mutually insulated. That is, the second insertion ports are mutually insulated along the first direction, and mutually electrically connected along the second direction.

Since a constitution in which the second insertion ports are connected with each other along the second direction is the same as the constitution in which the first insertion ports 106 are connected with each other as above, the description is not given. The second insertion ports along the first direction are insulated by the insulating substrate 21 existing between the mutual conductors 22a, 22b, . . . , 22z. For example, the terminal inserted into the second insertion port 206a is caught in the first direction by the conductor 22a provided along the second direction having a leaf spring contact shape, and is electrically connected in the second region along the second direction, but is insulated from other second insertion ports along the first direction.

The second insertion port is physically (spatially) connected to the first insertion port. For example, the second insertion port 206a has a space physically connected to the first insertion port 106a, and the first region containing the first insertion port 106a and the second region containing the second insertion port 206a are electrically connected by inserting a conductive connector having a predetermined length or more into the first insertion port 106a.

FIG. 2B is a B-B sectional view in FIG. 1. At the first layer 10, the first region which is not insulated by each island and all of the first insertion ports are electrically connected along the first direction may be included. It is thereby possible to generate a circuit using the same voltage or potential difference at the left and right islands such that, for example, when power supplies Vdd, Vcc are connected to the left island in FIG. 1, and the power supplies Vdd, Vcc are used at the right island. In the following description, first insertion ports 109a, 109b, . . . , 109z are electrically connected, first insertion ports 110a, 110b, . . . , 110z are electrically connected, and first insertion ports 111a, 111b, . . . , 111z are electrically connected at the first layer.

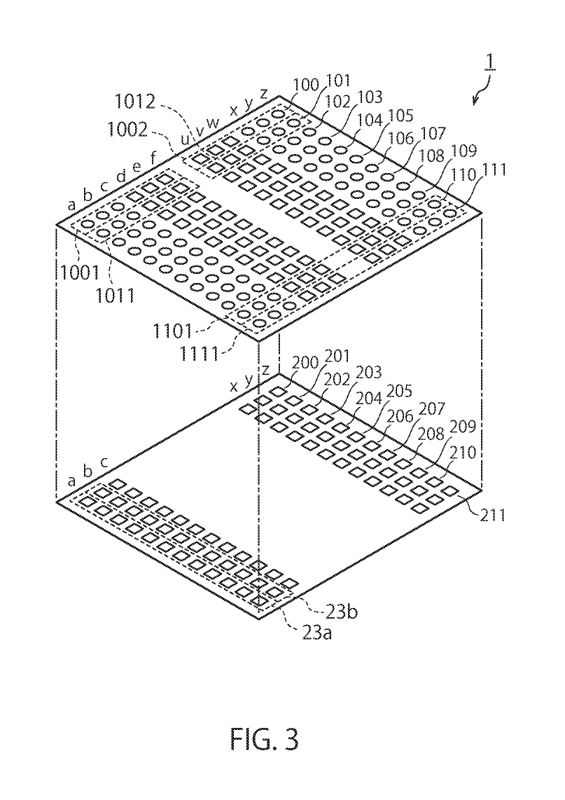

FIG. 3 is a view illustrating positional relationship of insertion ports regarding the first layer 10 and the second layer 20. There are corresponding first insertion ports for the second insertion ports existing at the second layer 20, but the corresponding second insertion port does not necessarily exist for each of all the first insertion ports. For example, the second insertion port 200a is physically connected to the first insertion port 100a, but a second insertion port physically connected to a first insertion port 100d does not exist.

A dotted line in the drawing indicates that the insertion ports existing in a region surrounded by the dotted line are electrically connected within the same region. On the first layer 10, for example, the first insertion ports provided at first regions 1001, 1002, 1011, 1012, . . . , 1101, 1111 are electrically connected with each other. On the other hand, for example, the first insertion ports provided in the first region 1001 and the first region 1002 are insulated from one another. At the second layer 20, for example, the second insertion ports provided at a second region 23a are electrically connected, meanwhile, the second insertion ports provided at the second region 23a and a second region 23b are insulated.

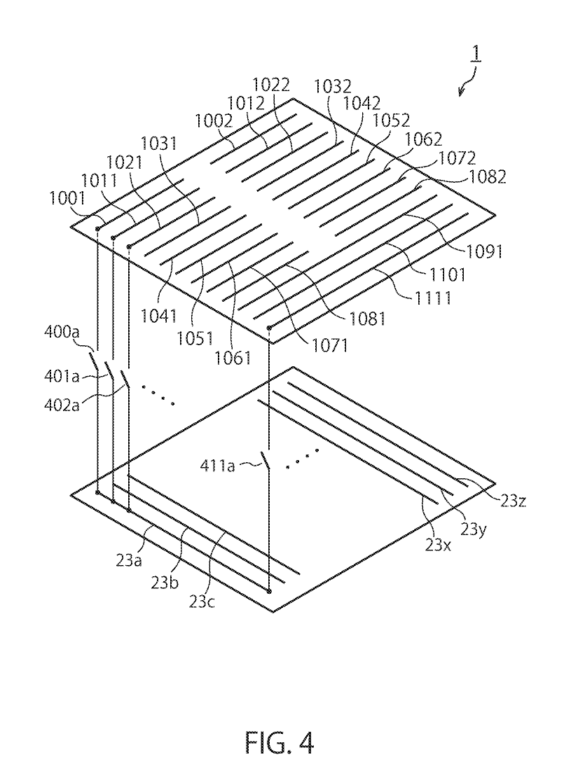

FIG. 4 is a circuit diagram where the connection relationship as above is schematically picked up. Connectors are provided between the first layer 10 and the second layer 20. For example, a switch 400a being the connector is provided between the first insertion port 100a and the second insertion port 200a, and the first insertion port 100a and the second insertion port 200a are electrically connected or electrically insulated.

For example, when the switch 400a is in a closed state, that is, when the first insertion port 100a and the second insertion port 200a are electrically connected, the first region 1001 of the first layer and the second region 23a of the second layer are in an electrically connected state. Under this state, for example, when a switch 411a is in an electrically connected state, the second region 23a of the second layer 20 and the first region 1111 of the first layer 10 are in an electrically connected state. That is, in this case, the first region 1001 and the first region 1111 of the first layer 10 are in an electrically connected state.

It is possible to electrically connect the first regions which are insulated on the first layer 10 through the second region which is electrically connected on the second layer 20.

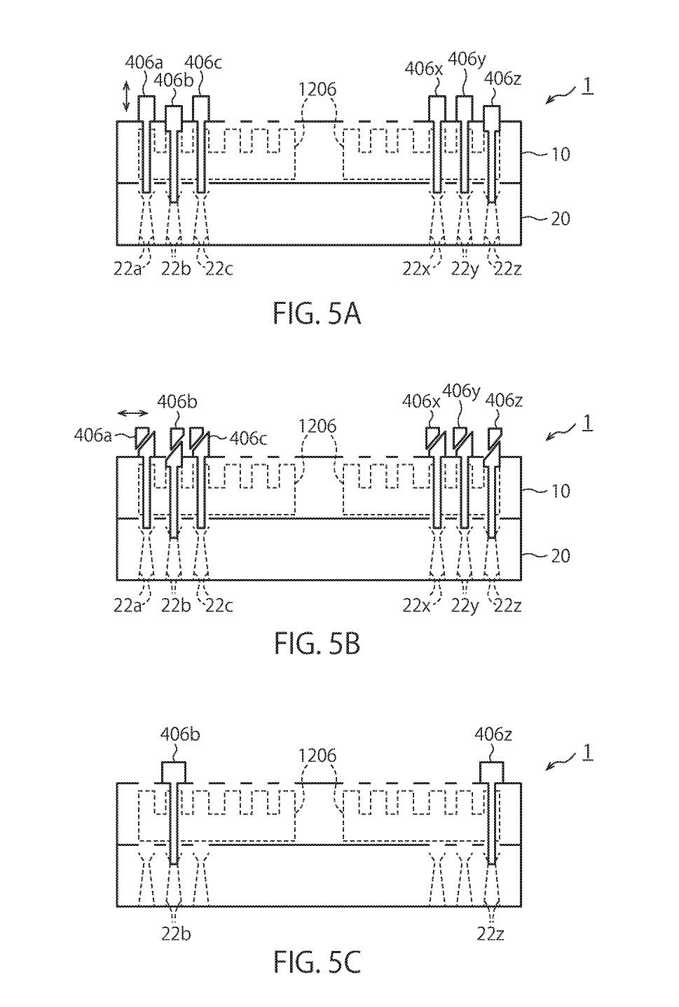

FIG. 5A to FIG. 5C are views illustrating examples of these connectors, and are schematic views of an A-A cross-section in FIG. 1. Note that there is a case when parts unnecessary for the explanation are not illustrated.

FIG. 5A is an example where a push-type toggle switch is used as a mechanical switch provided at the bread board 1 as the connector. A switch 406a is in contact with the conductor 1206 regardless of whether it is pressed-down, but is not in contact with the conductor 22a when it is not pressed-down. That is, the switch 406a is electrically connected only to the conductor 1206 when it is not pressed-down.

On the other hand, when the switch 406a is pressed-down, the switch 406a is in contact with both the conductor 1206 and the conductor 22a. That is, the conductor 1206 and the conductor 22a are electrically connected through the switch 406a. For example, the first insertion port 106a and the second insertion port 206a are electrically connected, and a first region 1061 and the second region 23a are electrically connected, by pressing-down the conductive switch 406a.

The “pressed-down” described here means that a switch is pushed-in from the first layer 10 toward a direction of the second layer 20 along the third direction, and it is not necessarily an expression indicating only to push downward in a vertical direction.

When a switch 406b and a switch 406z are pressed-down, and other switches 406a, 406c, 406x and 406y are not pressed-down, the first region 1061 and the second region 23b are electrically connected, and a first region 1062 and a second region 23z are electrically connected. Under this state, for example, when a not-illustrated switch 407b is pressed-down, the first region 1061 and a first region 1071 are electrically connected.

FIG. 5B is a view illustrating another example of the connector using a slide-type toggle switch as the mechanical switch. A switching direction of the mechanical switch can be converted into the first direction or the second direction without being limited to the switch operated in the third direction.

Further, in FIG. 5A, the mechanical switch may be a switch where up and down operations with respect to the third direction are reversed. It is thereby possible to raise the switch when the switch is in on-state, and it is easy to be visually grasped. As another example, there may be used a switch which changes its color when it is pressed-down. It is thereby also possible that the circuit state is easy to be visually grasped.

In each of FIG. 5A and FIG. 5B, a mechanical mechanism is not illustrated, but may be used accordingly. For example, in FIG. 5A, there may be provided a mechanism in which a switch which is pressed-down and turned on is pressed-down again to release the pressed-down state to turn off the switch by using a spring and a fastener.

FIG. 5C is a view illustrating another example of the connector. When the switch is turned off, that is when, for example, the first insertion port 106a and the second insertion port 206a are not electrically connected, nothing is done. When the switch is turned on, that is when, for example, the first insertion port 106b and the second insertion port 206b are connected, the connector is enabled by using a wire material such as a conductive jumper pin as the switch 406b.

In these FIG. 5A to FIG. 5C, the connectors are set to be the conductors, but all of the connectors are not necessarily the conductors, and it is only required that contact parts with a conductor provided at the first insertion port and a conductor provided at the second insertion port can be electrically connected. For example, an upper part than the first layer 10 may be formed with an insulator or covered with an insulator.

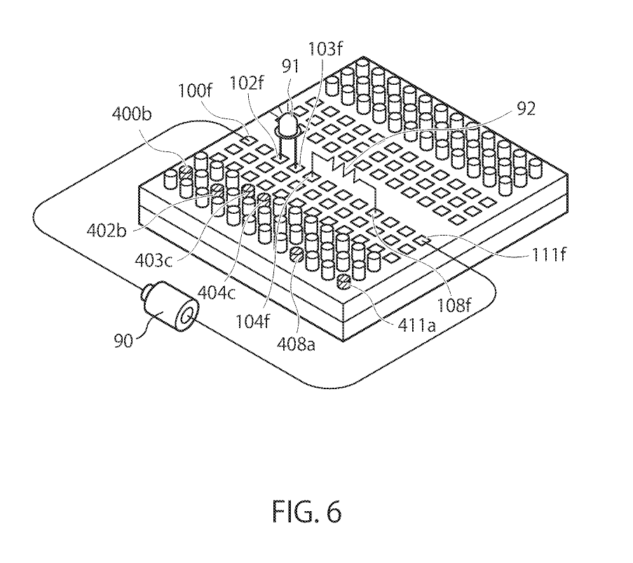

FIG. 6 is a view illustrating an example where an LED (light emitting diode) is lit on the bread board 1 as an example of a circuit using the bread board 1. The mechanical switches illustrated in FIG. 5A are used as the connectors.

A battery 90 is connected to a first insertion port 100f and a first insertion port 111f, an LED 91 is connected to a first insertion port 102f and a first insertion port 103f, and a resistor 92 is connected to a first insertion port 104f and a first insertion port 108f. Under this state, when none of the mechanical switches forming the connectors are pressed-down, the LED 91 does not light because the first regions connected to the battery 90 are independent in anode and cathode, respectively.

Here, when a switch 400b and a switch 402b are pressed-down, the first region 1001 where the anode of the battery 90 is connected and a first region 1021 where an anode of the LED 91 is connected are connected through the second region 23b of the second layer 20. That is, the anode of the battery 90 and the anode of the LED 91 are connected.

Similarly, a cathode of the LED 91 and one terminal of the resistor 92 are connected through a second region 23c by pressing-down a switch 403c and a switch 404c, and the other terminal of the resistor 92 and the cathode of the battery 90 are connected by pressing-down a switch 408a and a switch 411a. As a result, the LED 91 is lit due to a voltage between the anode and the cathode of the battery 90.

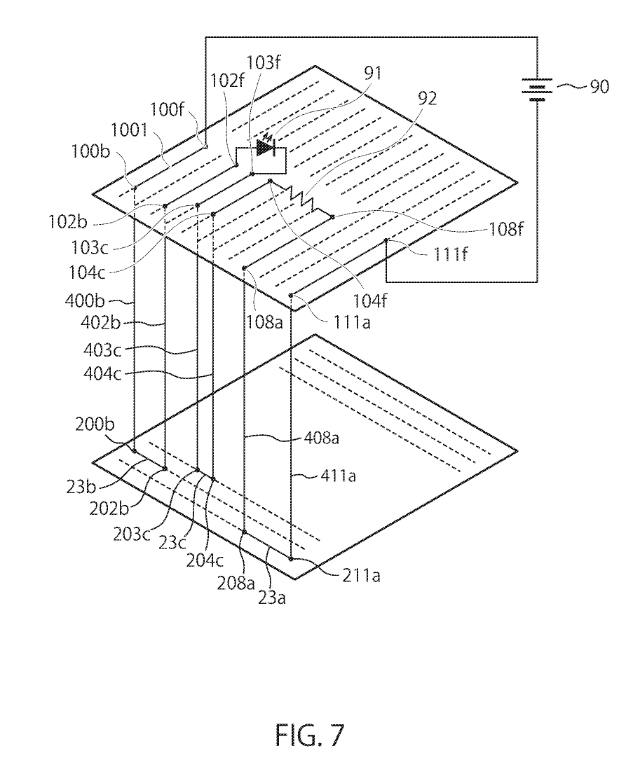

FIG. 7 is a circuit diagram illustrating a lighting circuit of the LED in FIG. 6. The anode of the battery 90 is connected to the first region 1001 through the first insertion port 100f. The first region 1001 is connected to the second region 23b through the switch 400b connecting between the first insertion port 100b and the second insertion port 200b. Similarly, the second region 23b and the first region 1021 are connected through the switch 402b, a first region 1031 and the second region 23c are connected through the switch 403c, the second region 23c and a first region 1041 are connected through the switch 404c, a first region 1081 and the second region 23a are connected through the switch 408a, and the second region 23a and the first region 1111 are connected through the switch 411a, respectively, and thereby, a closed circuit is formed. A circuit is able to be generated by electrically connecting between the first layer 10 and the second layer 20 by each region through the switch being the connector.

As described above, according to the present embodiment, it becomes possible to electrically connect the first regions which are mutually insulated on the first layer 10 by being intervened by the second layer 20. This connection is carried out by using the connectors (switches) connecting between the first layer 10 and the second layer 20. The connector may be a mechanical switch provided at the bread board 1, a wire material such as a jumper pin detachable from the bread board 1, or other connection elements. Further, since the connection state between the first regions at the first layer 10 can be changed by the switches, it becomes possible to try various dispositions of circuit elements in prototyping of a circuit design similar to a general bread board.

As stated above, the bread board 1 which does not require jumper wires to connect between insulated regions is enabled by using physical switches, though the jumper wires were required in the conventional bread board. As a result, the jumper wires do not exist on the bread board 1, to enable the circuit design with good visibility over a whole circuit.

When an analog switch is used for the connector, a resistance value becomes high due to an on-resistance or the like. When a semiconductor switch including an analog switch is used, it becomes weak for noise, easy to get out of order due to application of a current, a voltage of a rated value or more. Meanwhile, the problems as stated above are unlikely to occur by using the mechanical switch such as the toggle switch or the wire material such as the jumper pin as in the present embodiment. In addition, electricity is not used for switching of the switches, and therefore, a special electrical logic to operate the switches is unnecessary, to lead to suppression of power consumption.

### Modified Example of the First Embodiment

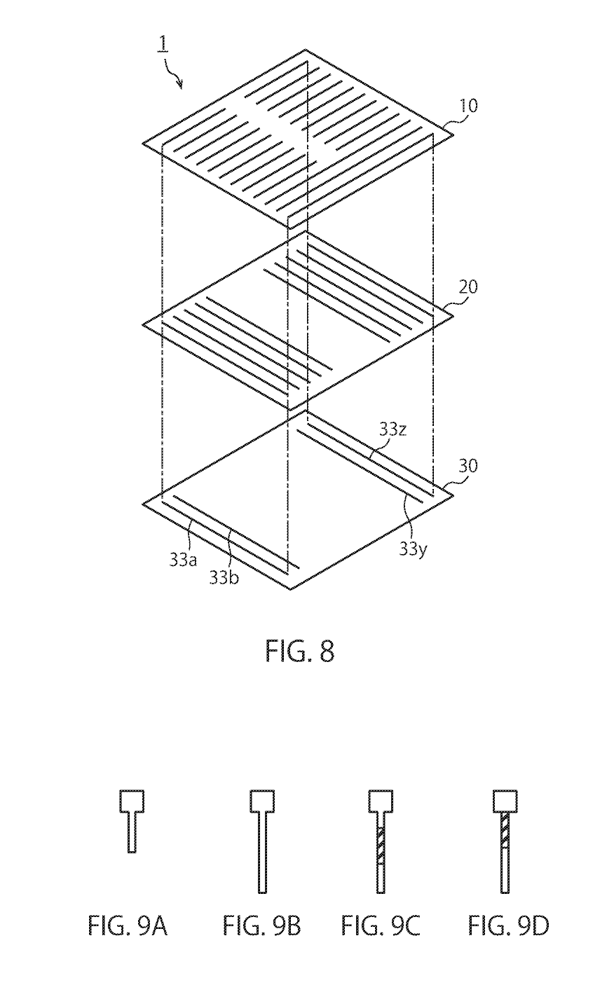

In the first embodiment, the bread board 1 has the two-layer structure, but the structure is not limited thereto, and the bread board 1 may have a further multilayer structure. FIG. 8 illustrates electrically connected regions in each layer of the bread board 1 having a three-layer structure as an example.

The first layer 10 and the second layer 20 are similar to the aforementioned first embodiment. Note that connection ports with third insertion ports of a third layer 30 exist at a rear surface of the second insertion ports of the second layer 20 as same as the first layer 10.

For example, the third layer 30 includes a third region 33a including third insertion ports 300a, 301a, . . . , 311a, similarly a third region 33b including third insertion ports 300b, . . . , 311b, a third region 33y including third insertion ports 300y, . . . , 311y, and a third region 33z including third insertion ports 300z, . . . , 311z.

Under this state, the third region 33a and the third region 33z are each set at the voltage Vdd, and the third region 33b and the third region 33y are each set at the voltage Vcc, and thereby, it is possible to use these voltages when a reference voltage is required, or these voltages are required as the power supply. The desired voltage can be applied by connecting the first region on the first layer 10 which needs to use the voltage and the third region on the third layer 30.

When the voltage is set at the third region of the third layer 30 as above, for example, a jack for power supply may be provided at the bread board 1. It is thereby also possible to set a potential of an arbitrary region of the first layer 10 or the second layer 20 to a desired value by connecting with the third layer 30.

FIG. 9 are views illustrating examples of a jumper pin as the connector used in case of the three-layer structure in FIG. 8. FIG. 9A is a jumper pin to connect between the first layer 10 and the second layer 20, and a length is sufficient as long as the jumper pin is in contact with both conductors of the first layer 10 and the second layer 20.

The jumper pin illustrated in FIG. 9B is a jumper pin to connect each of the first layer 10, the second layer 20 and the third layer 30, and it is formed to be connected to the conductors of respective layers.

The jumper pin illustrated in FIG. 9C is a jumper pin to connect between the first layer 10 and the third layer 30, a length thereof is the same as the length illustrated in FIG. 9B, and for example, a coating by an insulator is provided around a conductor at a part which may be in contact with the conductor of the second layer 20.

The jumper pin illustrated in FIG. 9D is a jumper pin to connect between the second layer 20 and the third layer 30, a length thereof is the same as the length illustrated in FIG. 9B, and an insulator is provided at a part which may be in contact with the conductor of the first layer 10.

The regions from the first layer 10 to the third layer 30 are able to be electrically connected by using the above-stated jumper pins illustrated in FIG. 9A to FIG. 9D. Head parts of these jumper pins may be respectively colored in different colors to thereby make the connected layers clear by the insertion port where the jumper pin is inserted. Further, a pin for the voltage Vdd and a pin for the voltage Vcc are colored in different colors to thereby make clear the voltage Vdd or the voltage Vcc applied thereto.

The number of layers may be four layers or more, and for example, a fourth region along the first direction connecting all of a to f, u to z in the first direction may be provided at a fourth layer with regard to each row of the first insertion ports. The first regions 1091, 1101, 1111 in FIG. 4 or the like may be divided into left and right islands. It is thereby possible to further freely design the first regions on the first layer 10. It goes without saying that the connectors are appropriately prepared.

### Second Embodiment

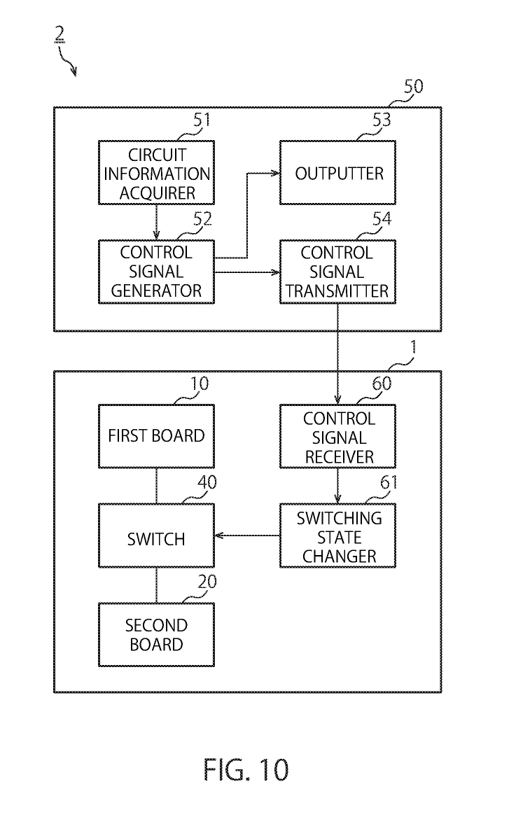

FIG. 10 is a block diagram illustrating functions of a bread board system 2 according to the present embodiment. The bread board system 2 includes the bread board 1 and a control device 50 which generates and outputs a control signal to switch switches 40 being the connectors between the first layer 10 and the second layer 20 of the bread board 1.

The control device 50 includes a circuit information acquirer 51, a control signal generator 52, an outputter 53, and a control signal transmitter 54.

The circuit information acquirer 51 acquires information regarding a circuit input thereto. The information regarding the circuit is, for example, a circuit diagram or the like where the closed circuit in FIG. 7 in the aforementioned embodiment is simplified. As another example, the information may be one where a plurality of circuit elements located through an input interface on a bread board displayed on a not-illustrated display and conductive wires connecting between terminals of the plurality of circuit elements are located. Regarding the conductive wires, a connection state of the terminals of the plurality of circuit elements may be illustrated in the drawing, or texts or tables presenting connected terminals from among the terminals of the plurality of circuit elements are used to express the connection state in a graphic format. The circuit information acquirer 51 acquires the information regarding the circuit as above.

The control signal generator 52 generates information of the switches 40 indicating at least the insertion ports to be connected between the first layer 10 and the second layer 20 from the acquired information regarding the circuit, as the control signal. Not only the information of the switches 40 but also information of a circuit element disposition may be generated. For example, when a later-described switching state changer 61 is an FPGA (field programmable gate array), the optimized FPGA generating a signal to control the switches 40 may be generated as the control signal.

The outputter 53 outputs the control signal of the switches 40 generated by the control signal generator 52 and disposition information of the circuit elements. For example, various information may be output as video on a display or as data. When the optimization of the FPGA is carried out, a DSL (domain specific language) (or an HDL (hardware description language) and so on describing the FPGA may be output.

The control signal transmitter 54 transmits the generated control signal to the bread board 1. The transmission may be wired or wireless, or the signal may be transmitted in a closed network or via a network such as Internet. That is, any type of transmission may be used.

The circuit information acquirer 51 may acquire the data or the like previously generated by the control signal generator 52 and output by the outputter 53. It is thereby possible that the circuit information acquirer 51 receives the control signal in a once generated circuit or the control signal of the switches 40 in the circuit when the equivalent circuit is generated at a remote place, and so on, as data, and acquires the data at the control device 50.

The bread board 1 includes a control signal receiver 60 which receives the control signal of the switches transmitted from the control device 50 and the switching state changer 61 which switches the state of the switches 40 being the connectors of the bread board 1 based on the received control signal in addition to the constitution in the aforementioned embodiment.

In FIG. 10, the control signal receiver 60 and the switching state changer 61 are included in the bread board 1, but the constitution is not limited thereto, and they may be provided at a different device from the bread board 1, and may be connected to the bread board 1 according to need.

The switching state changer 61 changes the state of the switches 40 existing between the first layer 10 and the second layer 20 based on the control signal, to thereby change the connection states between the first insertion ports and the second insertion ports. The electrical connection relationship between the first insertion ports on the first layer 10 through the second layer 20 changes due to the change in the connection states. It is thereby possible to generate an equivalent circuit as the circuit acquired by the circuit information acquirer 51 by the circuit element disposition output from the outputter 53 and the connection relationship controlled by this control signal.

This switching state changer 61 changes the switches based on the control signal, where the switching is performed by, for example, applying a current to each switch 40 including a relay circuit. The switching state changer 61 may be mounted, for example, while including the FPGA to apply a current to the relay circuit based on the control signal. When the switching state changer 61 is the FPGA, the control signal generator 52 carries out the optimization of the FPGA as the control circuit of the switch 40, and the control signal transmitter 54 outputs an optimized FPGA code as described above.

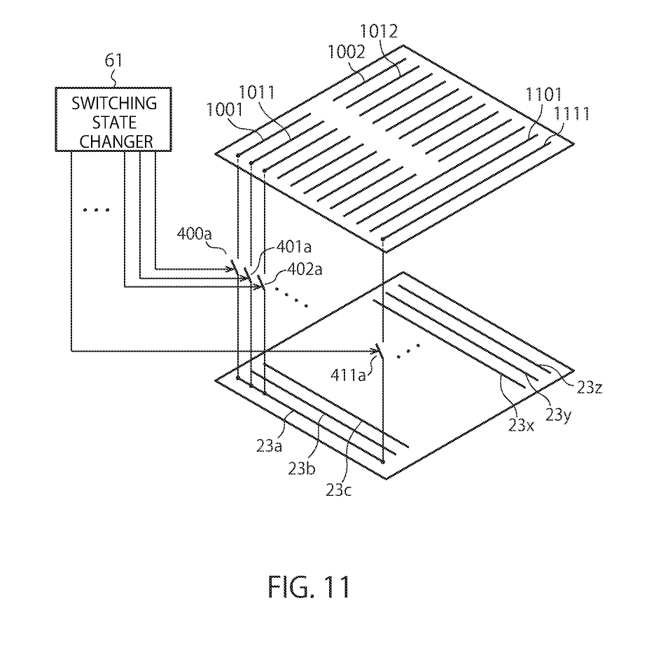

FIG. 11 is a circuit diagram illustrating a flow of the control signal of the switching state changer 61 of the bread board 1. The switching state changer 61 changes the state of each switch 40 by transmitting different signals to each of the plurality of switches 40.

The control signal receiver 60 inputs the received code of the FPGA into the switching state changer 61, and the switching state changer 61 reconfigures the included FPGA by using the received code of the FPGA. The switching state changer 61 switches the on/off state of each switch 40 by properly applying the current to the relay circuit provided at each switch 40 by using the reconfigured FPGA.

As stated above, the switch 40 can be formed without using a semiconductor. Note that the relay circuit and the FPGA are examples, and they are not limited thereto. For example, an actuator which is mechanically driven by a voltage may be used for the relay circuit. A small-sized CPU or the like which enables to change the state of the switch 40 by a program may be mounted instead of the FPGA. A semiconductor control mechanism such as a shift register may be used. Further, analog switches may be used for the switches 40, and the analog switches may be operated from the FPGA.

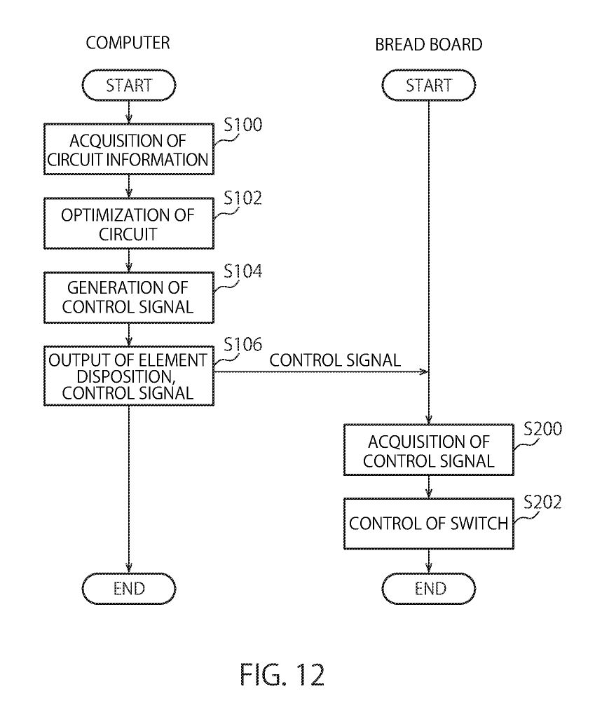

FIG. 12 is a flowchart illustrating a flow of processes of the bread board system 2 according to the present embodiment. The above-stated processes are described by using this flowchart.

First, the circuit information acquirer 51 acquires the circuit information (step S100). As stated above, the circuit information is the data indicating the circuit designed on the computer, or the already obtained element disposition or the state of the switches.

Next, the control signal generator 52 optimizes the circuit (step S102). The optimization of the circuit means to optimize the circuit element disposition and the connection relationship between the first layer 10 and the second layer 20 when the circuit information is designed on the computer. This optimization is carried out so as not to break the connection between the plurality of circuit elements in the acquired circuit information. When the circuit disposition and the control signal of the switches are acquired by the circuit information acquirer 51, this step S102 may be omitted.

Next, the control signal generator 52 generates the control signal of the switches (step S104). This generation of the control signal may include not only the signals controlling the switches but also the generation of data such as the DSL after the FPGA is optimized as described above. That is, when the switching state changer 61 is constituted by including the FPGA, the optimization of the FPGA is carried out in this step S104.

Next, the outputter 53 or the control signal transmitter 54 outputs the element disposition and the control signal (step S106). When the control device 50 and the bread board 1 are connected, for example, the circuit element disposition on the bread board is output from the outputter 53, and the control signal is transmitted from the control signal transmitter 54 to the bread board 1. When the data of the circuit disposition and the control signal are desired, the outputter 53 properly outputs these data. It becomes possible to reproduce the equivalent circuit in a different environment by storing the data of the circuit disposition and the control signal, and by transmitting to other developers and inputting the circuit disposition and the control signal to another control device 50.

Next, the bread board 1 receives the control signal transmitted from the control signal transmitter 54 at the control signal receiver 60 and acquires (step S200). The acquired control signal is input to the switching state changer 61.

Next, the switching state changer 61 controls the switches (step S202). When the switching state changer 61 includes the FPGA, and the control of the switches 40 is carried out by using the FPGA, the reconfiguration of the FPGA is carried out in this step. The states of the switches are properly switched by the reconfigured FPGA.

The connection state of the bread board 1 is thereby changed, and the circuit regarding the information acquired by the circuit information acquirer 51 is formed by disposing the circuit elements on the bread board 1 based on the circuit element disposition output from the outputter 53.

As stated above, the bread board 1 having the multilayer structure which does not use the jumper wires is also enabled according to the present embodiment. Further, according to the bread board system 2 of the present embodiment, the circuit element disposition and the control signal of the switches 40 can be transmitted to, for example, a remote place, and therefore, an equivalent circuit can be easily formed also at a distant place. Note that in any of the above-stated cases, each switch in itself is driven mechanically, and problems occurred in semiconductor switches or the like can be avoided similar to the aforementioned embodiment.

Though the operation of the switches 40 in itself is carried out by, for example, the FPGA, the prototyped circuit in itself is not formed on the FPGA. It is therefore possible to easily change a signal flowing direction without changing a direction of a transistor or the like constituting the switch 40 even when the switch 40 is the analog switch. Besides, an input signal is not limited to a digital signal and may be an analog signal because the circuit is not formed on the FPGA.

### Usage Example

Hereinafter, concrete usage examples of the above-stated each embodiment are described.

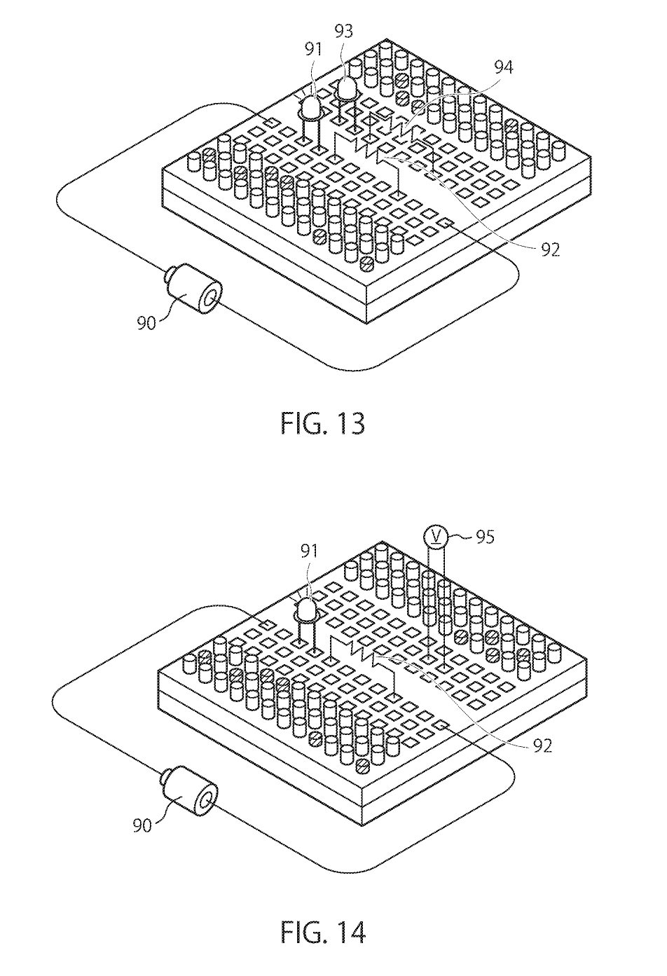

FIG. 13 is a view illustrating one concrete example, and is a concrete example of the lighting circuit of the LED illustrated in FIG. 6. The lighting circuit of the LED illustrated in FIG. 6 is formed at the left side island on the bread board 1, but in FIG. 13, an LED 93 and a resistor 94 are disposed at a right side island to be left-right symmetry. Further, switches 402y, 403x, 404x, 408z are turned on.

Such disposition enables to easily switch lighting to the LED 93 when, for example, the LED 91 is out of order. For example, switches 409b, 409y, 410c, 410x are further turned on. The LED 93 is disposed in parallel to the LED 91 by switching the switches as above, and the LED 93 lights on. Switching of a component in failure can be smoothly exchanged such as switching the LED 91 into an LED not in failure, or the like during the LED 93 is lit. At this time, the switches 402b, 403c may be turned off.

Further, it becomes possible to determine the circuit element which is out of order between the LED 91 and the resistor 92 when the LED 91 does not light, by previously generating the disposition as above. When the LED 91 does not light, a circuit combining the LED 91 and the resistor 94, a circuit combining the LED 93 and the resistor 92 are generated on the bread board 1, and thereby, it is possible to determine which component is out of order. It is described when the number of elements is two, but it is effective when the number of elements increases, and the failed component can be determined without breaking the configuration of the circuit or without applying a probe of a measuring device to each terminal of the elements on the bread board 1.

For example, when a relatively fragile element such as an electrolytic capacitor is used, the fragile elements may be disposed multiply. It is thereby possible to enable what is called a cold standby state.

FIG. 14 is an example including a voltmeter. It becomes possible to measure a voltage between terminals of respective elements without applying a probe of the voltmeter to the terminal of each element by disposing a voltmeter 95 as illustrated in the drawing.

The voltmeter is connected to first insertion ports 107v, 108v, and switches 407x, 408y, 409x, 410y are turned on. When a voltage drop at the LED 91 is required to be known under this state, the switches 409b, 410c are turned on. The voltage drop at the LED 91 can be thereby measured. It is the same as for the resistor 92, and the voltage drop at the resistor 92 can be measured by turning on switches 409c, 410a.

The voltage drop of each circuit element can be measured by changing the connection relationship of the connector without moving the probe so as to be directly in contact with the terminal. For example, an ammeter, a wattmeter, and so on can be disposed without being limited to the voltmeter.

Hereinafter, concrete mounting modes of switches are described. In the above-stated first embodiment, the second insertion ports are provided at the second layer 20, but the second insertion ports are not an essential constitution. For example, the second layer 20 may include the second regions which are electrically connected by a conductor along the second direction, on the substrate.

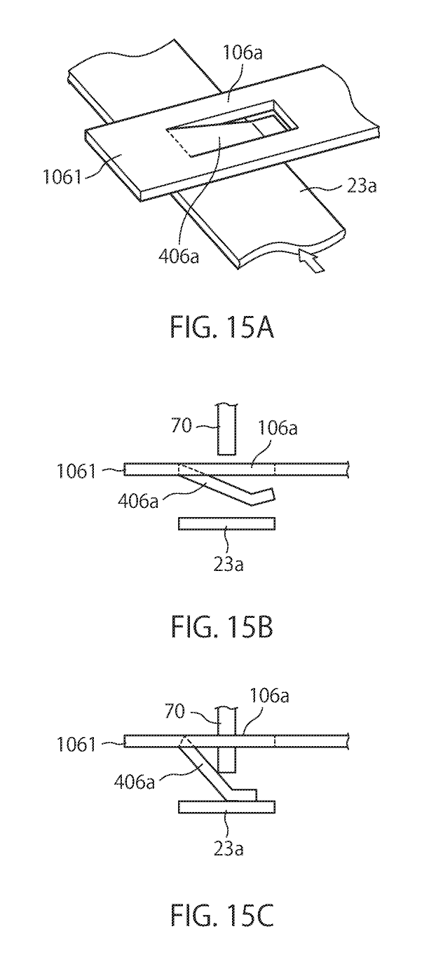

FIG. 15A to FIG. 15C are views illustrating an example where a part of the first region is movable. As illustrated in FIG. 15A, the connector 406a is a conductor formed by, for example, a mover provided at a metal wiring at the first insertion port 106a. This mover is formed to be in contact with the second region 23a by applying a force from the first region 1061 to a direction of the second region 23a.

FIG. 15B is a side view of FIG. 15A, and it is a view when seen from an arrow direction in FIG. 15A. As illustrated in FIG. 15B, the connector 406a is provided in the first region 1061. For example, a switch changer 70 such as a jumper pin is inserted from the first insertion port 106a, and when it is pressed-in for a predetermined distance or more, the connector 406a and the second region 23a are electrically connected as illustrated in FIG. 15C. The first region 1061 and the second region 23a are thereby mutually electrically connected. When the force applied on the connector 406a becomes weak, the connector returns to the state illustrated in FIG. 15B, and the first region 1061 and the second region 23a are shifted to an insulated state.

The switch changer 70 may be a conductor or an insulator. As illustrated in FIG. 5, the switch changer 70 may be a switch provided at the first layer 10, or a jumper pin as described in the aforementioned first embodiment. Further, the switch changer 70 may be provided at the switching state changer 61 described in the aforementioned second embodiment.

When the switch changer is designed as above, the switch changer 70 may be a piezoelectric actuator provided at the switching state changer 61, or a part which is pushed-out by the piezoelectric actuator. For example, the switching state changer 61 is located on each first insertion port which can be connected to the second region, and the piezoelectric actuator which is located at the switching state changer 61 such that the switch changer 70 is pressed-in when the voltage is applied as illustrated in FIG. 15C. The control by the FPGA or the like is enabled according to external request by the setting as above.

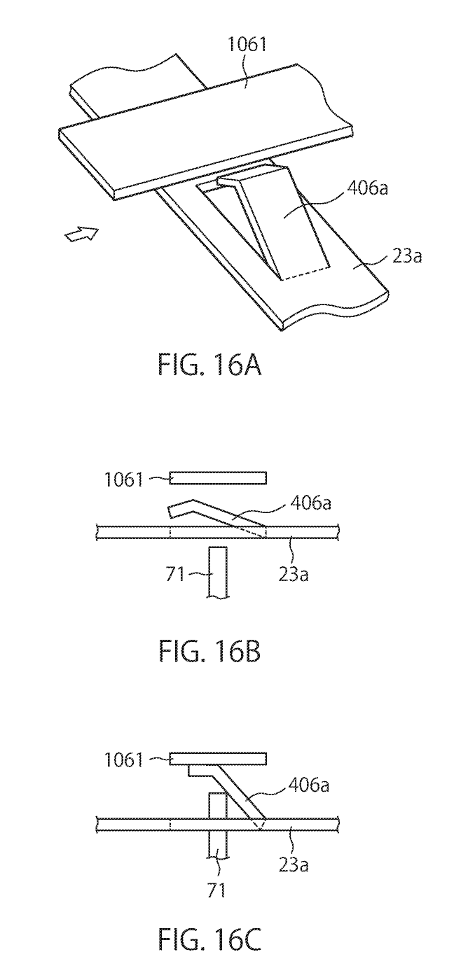

FIG. 16A to FIG. 16C are views where the above-stated constitution between the first region and the second region are reversed. As illustrated in FIG. 16A, the connector 406a is, for example, a mover formed at the metal wiring being the second region 23a. As illustrated in FIG. 16B, the connector 406a is pressed-in from the second region 23a side toward the first region 1061 side, and thereby, the second region 23a and the first region 1061 are electrically connected as illustrated in FIG. 16C.

The connector 406a is switched by a switch changer 71. This switch changer 71 may be a jumper pin or the like, or one controlled by a piezoelectric actuator or the like as described in FIG. 15.

The connector 406a enables the connection without being intervened by the first insertion port 106a. For example, insertion ports such as the first insertion ports 106a, 106b, 106c, and the first insertion ports 106x, 106y, 106z to be connected to the second region as illustrated in FIG. 2A can be omitted by providing the mover being the connector 406a at the second region 23a. Further, the leaf spring shaped conductor 22a or the like becomes unnecessary also at the second layer 20, and therefore, a thickness of the second layer 20 can be reduced. That is, both of a length of the first layer 10 along the first direction and a length of the second layer 20 along the third direction can be reduced.

There is a case when the first regions which are electrically connected cannot be visually recognized by using the connector as stated above. An indicator or the like may be provided at each first region so as to avoid the case. For example, the indicator may emit some colors to determine the connected first regions by the color, or the connection state may be determined by lighting state, for example, a state such as a constant lighting or a blinking, or a brightness and darkness state, or may be determined by using both the color and the lighting state.

As another example, the connector 406a may be an analog switch including a MOSFET (metal-oxide-semiconductor field-effect-transistor) or a bipolar transistor. In this case, for example, the first layer 10 is formed as same as a general bread board, the second region 23a is formed as a metal wiring along the second direction as the second layer 20, and the first region 1061 and the second region 23a are connected through the analog switch, to thereby enable to turn on/off the connection state according to the request from exterior. The request from exterior may be signal processing through the FPGA or the like similar to the aforementioned second embodiment. This signal processing is, for example, processing by software, and information processing by the software is concretely achieved by using hardware resources (switches).

That is, in a general bread board having a plurality of first regions which are electrically connected along the first direction, a plurality of second regions which are electrically connected along the second direction are formed at a bottom surface at an inside of the bread board, and the connection states between the plurality of first regions and the plurality of second regions may be changed by the connectors. Also in this case, each of the switches may be a mechanical switch, or may be an analog switch or the like.

As stated above, tamper resistance can also be secured by prohibiting visual recognition of the connection relationship between the first region and the second region by observing from the first layer 10. When some part of the bread board 1 is broken, for example, a part or all of the states of the connectors are fixed to either an on or off state, and thereby, the tamper resistance can further be improved. In this case, positions of the circuit elements can be disposed at arbitrary positions free from the connection relationship not to be visually recognized, and the tamper resistance can be improved also from this point.

There is described the bread board 1 including insertion ports where general lead lines are inserted as detachers of terminals, in all of the above-stated embodiments and modified examples, and so on, but the bread board is not limited to one using the insertion ports. For example, the bread board using DIP sockets as sockets, or sockets with other various shapes, sizes and so on are attached/detached on the first layer 10, and these sockets and so on and the first region are made to be connectable. The connection state of the electrically insulated first regions can be controlled through the second region and the connectors even when lead lines are not used for connection, and various circuits are able to be formed. That is, terminal detachers may each have a shape capable of attaching/detaching the terminals of the circuit elements suitable for purposes without being limited to insertion ports.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A bread board, comprising:
a first layer comprising a plurality of first regions each including at least one terminal detacher which is electrically connected to a terminal, and the terminal detachers contained in an identical one first region from among the plurality of first regions are mutually electrically connected, but are electrically insulated from the terminal detachers contained in other first regions;
a second layer comprising a plurality of second regions and forms a multilayer structure with the first layer; and
connectors each of which electrically connects the second region of the second layer and a predetermined first region of the first layer, and the plurality of first regions which are mutually insulated are electrically connected through the connector and the second region.

2. The bread board according to claim 1, wherein
the at least one terminal detacher is a plurality of first insertion ports provided on the first layer, and the plurality of first insertion ports are provided on the first layer along a first direction and a second direction which is different from the first direction,
each of the plurality of first regions is the first region including the plurality of first insertion ports along the first direction,
the second layer includes a plurality of second insertion ports provided along the second region, and each of which is physically connected to the predetermined first insertion port,
the first layer and the second layer form a multilayer structure along a third direction which is approximately perpendicular to the first direction and the second direction, and
each of the plurality of second regions includes the plurality of second insertion ports along the second direction, and the second insertion ports contained in an identical one second region from among the plurality of second regions are mutually electrically connected.

3. The bread board according to claim 1, wherein
the at least one terminal detacher is a plurality of first insertion ports provided on the first layer, and the plurality of first insertion ports are provided on the first layer along a first direction and a second direction which is different from the first direction,
each of the plurality of first regions is provided along the first direction,
each of the plurality of second regions is provided along the second direction,
the connector is a conductor connected to the first region and connectable to the second region or a conductor connected to the second region and connectable to the first region.

4. The bread board according to claim 1, wherein
the connector changes a connection state by a mechanical switch.

5. The bread board according to claim 1, wherein
the connector changes a connection state by a detachable wire material.

6. The bread board according to claim 1, wherein
a second circuit element which is equivalent to a first circuit element disposed at the terminal detacher is disposed such that each terminal of the second circuit element is insulated from the corresponding terminal at the first circuit element, and when the first circuit element gets out of order, the second circuit element is used as an alternative element of the first circuit element by changing a connection relationship of the connectors.

7. The bread board according to claim 1, wherein
a measuring instrument is disposed at the terminal detacher, connected to a terminal of an arbitrary circuit element disposed on the first layer by changing a connection relationship of the connectors to measure a state at the circuit element.

8. A bread board, comprising:
a layer which includes a plurality of regions, each of the plurality of regions includes at least one terminal detacher electrically connected to a terminal, and the terminal detachers contained in an identical one region from among the plurality of regions are mutually electrically connected, but are electrically insulated from the terminal detachers contained in other regions; and
a switch which electrically connects arbitrary regions with each other from among the plurality of electrically insulated regions according to a request from exterior.

9. The bread board according to claim 8, further comprising:
a control signal receiver which receives a control signal controlling the switch; and
a switching state changer which changes a state of the switch based on the received control signal.

10. The bread board according to claim 9, wherein
the switching state changer includes a semiconductor control mechanism.

11. A bread board system, comprising a computer including:
the bread board according to claim 9;
a control signal generator which generates a control signal controlling the switch; and
a control signal transmitter which transmits the generated control signal to the control signal receiver.

12. The bread board system according to claim 11, wherein
the switch includes a relay circuit, and
the switching state changer changes a state of the switch by changing a connection state of the relay circuit based on the control signal.

13. The bread board system according to claim 11, wherein
the switch includes an analog switch, and
the switching state changer changes a state of the switch by changing a connection state of the analog switch based on the control signal.

14. A non-transitory computer-readable medium having a computer program stored therein where the computer program controls a switch in a bread board, the bread board including: a layer which includes a plurality of regions, each of the plurality of regions includes a plurality of terminal detachers each electrically connected to a terminal, and the terminal detachers contained in an identical one region from among the plurality of regions are mutually electrically connected, but are electrically insulated from the terminal detachers contained in other regions; and
the switch which electrically connects the electrically insulated regions with each other,
the computer program which when executed by a computer, causes the computer to perform processing of steps comprising:
generating a control signal which controls the switch to electrically connect arbitrary regions with each other from among the electrically insulated plurality of regions based on a predetermined data indicating connection relationship of the regions; and
transmitting the generated control signal to the bread board.

15. The non-transitory computer-readable medium according to claim 14, having the computer program stored therein which when executed by the computer, causes the computer to perform processing of steps further comprising:
switching the switch based on the transmitted control signal.
